(19) United States
(12) Patent Application Publication
(10) Pub. No.: US 2023/0005739 A1
(43) Pub. Date: Jan. 5, 2023

(54) Method For Processing Workpiece, Plasma Processing Apparatus And Semiconductor Device

(71) Applicants: Beijing E-Town Semiconductor Technology Co., Ltd., Beijing (CN); Mattson Technology, Inc., Fremont, CA (US)

(72) Inventors: Fei Yu, Wuhan (CN); Mengyang Xin, Wuhan (CN); Junliang Li, Wuhan (CN)

(21) Appl. No.: 17/489,203

(22) Filed: Sep. 29, 2021

(30) Foreign Application Priority Data
Jun. 30, 2021 (CN) 202110734423.6

(51) Int. Cl. H01L 21/02; H01J 37/32

(52) U.S. Cl. CPC H01L 21/02236; H01J 37/321; H01L 21/02164; H01J 2237/332

(57) ABSTRACT

A method for processing a workpiece, a plasma processing apparatus, and a semiconductor device which relate to the field of semiconductor manufacturing are provided. The method includes: placing the workpiece on a workpiece support in a chamber, the workpiece includes an substrate, a portion of the substrate is exposed; performing a flushing process on the workpiece by generating one or more species using a plasma from a process gas to create a mixture, the workpiece is exposed to the mixture; and applying a bias power during the flushing process to form an oxide layer with a preset thickness on the portion of the substrate. In this way, an oxide layer with a preset thickness is obtained after the flushing process.

### PRIORITY CLAIM

The present application claims the benefit of priority of People's Republic of China Application 202110734423.6, filed on Jun. 30, 2021, which is incorporated herein by reference.

### TECHNICAL FIELD

The present disclosure relates to the technical field of semiconductor manufacturing, and in particular to a method for processing a workpiece, a plasma processing apparatus, and a semiconductor device.

### BACKGROUND

After some etching treatments, a portion of the substrate, for example, a portion of silicon substrate will expose the substrate material. In this case, the exposed silicon substrate will generate an oxide layer due to natural oxidation; however, in the existing flushing process, the thickness of the formed oxide layer cannot be controlled.

### SUMMARY

Aspects and advantages of the disclosure will be set forth in part in the following description, or may be obvious from the description, or may be learned through practice of the embodiments. The present disclosure provides a method for processing a workpiece, a plasma processing apparatus, and a semiconductor device.

According to an aspect of the present disclosure, a method for processing a workpiece is provided. The method includes placing the workpiece on a workpiece support in a chamber. The workpiece includes a substrate. A portion of the substrate is exposed. The method includes performing a flushing process on the workpiece, by generating one or more species using a plasma from a process gas to create a mixture. The workpiece is exposed to the mixture. The method further includes applying a bias power during the flushing process to form an oxide layer with a preset thickness on the portion of the substrate.

In a specific example of the present disclosure, the mixture has a pressure and the flushing process has a time, and at least one parameter of the bias power, the pressure of the mixture, and the time of the flushing process affects a sensitivity of a thickness of the oxide layer to at least another parameter of the bias power, the pressure of the mixture, and the time of the flushing process.

In a specific example of the present disclosure, the bias power acts on the mixture in the chamber to affect a flow of the mixture in the chamber.

In a specific example of the present disclosure, the sensitivity is a slope value of the thickness of the oxide layer versus at least one parameter of the bias power, the pressure of the mixture, and the time of the flushing process.

In a specific example of the present disclosure, the pressure affects the sensitivity of the thickness of the oxide layer to the bias power.

In a specific example of the present disclosure, the pressure is the pressure in the chamber where the mixture is located.

In a specific example of the present disclosure, the pressure is in a range of about 5 mTorr (mt) to about 90 mt.

In a specific example of the present disclosure, the method further includes decreasing the pressure from a first pressure value to a second pressure value, to increase the sensitivity of the thickness of the oxide layer to the bias power from a first sensitivity to a second sensitivity, the first pressure value corresponds to the first sensitivity, and the second pressure value corresponds to the second sensitivity.

In a specific example of the present disclosure, the bias power affects the sensitivity of the thickness of the oxide layer to the time of the flushing process.

In a specific example of the present disclosure, the method further includes: increasing the bias power from a first bias power to a second bias power, to increase the sensitivity of the thickness of the oxide layer to the time from a third sensitivity to a fourth sensitivity, the first bias power corresponds to the third sensitivity, and the second bias power corresponds to the fourth sensitivity

In a specific example of the present disclosure, the bias power is in a range of about 50 watts to about 200 watts.

In a specific example of the present disclosure, the bias power is proportional to the preset thickness.

In a specific example of the present disclosure, the preset thickness is in a range of about 20 angstroms to about 50 angstroms.

According to another aspect of the present disclosure, a plasma processing apparatus is provided. The plasma processing apparatus includes a plasma chamber operable to receive a process gas. The plasma processing apparatus includes a processing chamber having a workpiece support operable to support a workpiece and a bias electrode for generating a bias power. The workpiece includes an substrate. A portion of the substrate is exposed. The bias electrode is arranged under the workpiece support. The plasma processing apparatus includes an inductive element operable to induce a plasma from the process gas. The plasma processing apparatus includes a bias source configured to provide a radio frequency (RF) power to the inductive element and the bias electrode. The plasma processing apparatus includes a controller configured to control the inductive element, the bias electrode and the bias source to implement a flushing process. The flushing process includes operations. The operations include providing a first RF power to the inductive element to generate the plasma from the process gas to generate a mixture. The mixture includes one or more species, the workpiece in the processing chamber is exposed to the mixture for a flushing process. The operations further include providing a second RF power to the bias electrode to apply the bias power during the flushing process, so that an oxide layer with a preset thickness is formed on the portion of the substrate.

In a specific example of the present disclosure, the processing chamber and the plasma chamber are the same chamber.

In a specific example of the present disclosure, the mixture has a pressure and the flushing process has a time, at least one parameter of the bias power, the pressure of the mixture, and the time of the flushing process affects a sensitivity of a thickness of the oxide layer to at least another parameter of the bias power, the pressure of the mixture, and the time of the flushing process.

In a specific example of the present disclosure, the sensitivity is a slope value of the thickness of the oxide layer versus at least one parameter of the bias power, the pressure of the mixture, and the time of the flushing process.

In a specific example of the present disclosure, the pressure affects the sensitivity of the thickness of the oxide layer to the bias power.

In a specific example of the present disclosure, the pressure is the pressure in the processing chamber where the mixture is located.

In a specific example of the present disclosure, the pressure is in a range of about 5 mt to about 90 mt.

In a specific example of the present disclosure, the controller is also configured to decrease the pressure from a first pressure value to a second pressure value, to increase the sensitivity of the thickness of the oxide layer to the bias power from a first sensitivity to a second sensitivity. The first pressure value corresponds to the first sensitivity, and the second pressure value corresponds to the second sensitivity.

In a specific example of the present disclosure, the bias power affects the sensitivity of the thickness of the oxide layer to the time of the flushing process.

In a specific example of the present disclosure, the controller is further configured to increase the bias power from a first bias power to a second bias power, to increase the sensitivity of the thickness of the oxide layer to the time from a third sensitivity to a fourth sensitivity. The first bias power corresponds to the third sensitivity, and the second bias power corresponds to the fourth sensitivity.

In a specific example of the present disclosure, the bias power is in a range of about 50 watts to about 200 watts.

In a specific example of the present disclosure, the bias power is proportional to the preset thickness.

In a specific example of the present disclosure, the preset thickness is in a range of about 20 angstroms to about 50 angstroms.

According to another aspect of the present disclosure, there is provided a semiconductor device including a workpiece processed by a method as described above. The workpiece includes a substrate, and an oxide layer formed on the exposed area of the substrate has a thickness of about 20 angstroms to about 50 angstroms.

An embodiment according to the present disclosure solves the problem that the thickness of the oxide layer formed on the exposed substrate cannot be controlled in the prior art, and obtain an oxide layer with preset thickness after the flushing process, and lays a foundation for improving the yield and satisfying different needs of users.

These and other features, aspects and advantages of the present disclosure will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure to one of ordinary skill in the art is set forth more particularly in the remainder of the specification, including reference to the accompanying figures, in which:

FIG. 1 is a schematic diagram of a processing flow in a specific example of a method for processing a workpiece according to an embodiment of the present disclosure;

FIG. 2 is a schematic diagram of the implementation flow of a method for processing a workpiece according to an embodiment of the present disclosure;

FIG. 3A is a schematic diagram of the relationship between the bias power and the thickness of the silicon oxide layer at a lower pressure obtained by the method for processing a workpiece according to an embodiment of the present disclosure;

FIG. 3B is a schematic diagram of the relationship between the bias power and the thickness of the silicon oxide layer at a higher pressure obtained by the method for processing a workpiece according to an embodiment of the present disclosure;

FIG. 4A is a schematic diagram of the relationship between time and the thickness of the silicon oxide layer at higher bias power obtained by the method for processing a workpiece according to an embodiment of the present disclosure;

FIG. 4B is a schematic diagram of the relationship between time and the thickness of the silicon oxide layer at lower bias power obtained by the method for processing a workpiece according to an embodiment of the present disclosure;

FIG. 5A is a schematic diagram of the relationship between the bias power and the thickness of the silicon oxide layer at longer time obtained by the method for processing a workpiece according to an embodiment of the present disclosure;

FIG. 5B is a schematic diagram of the relationship between the bias power and the thickness of the silicon oxide layer at shorter time obtained by the method for processing a workpiece according to an embodiment of the present disclosure; and

FIG. 6 is a cross-sectional view of a plasma processing apparatus in a specific example according to an embodiment of the present disclosure.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

The flushing process is the last step in an etching process, such as a plasma etching process. In some examples, a plasma of oxygen (O₂) or a plasma obtained after mixing oxygen (O₂) and nitrogen (N₂) can be used to remove organic polymers such as photoresist that are not completely etched away in the etching step.

Here, it should be noted that, in some examples, a portion of the substrate is etched during the etching process to expose the substrate material. For example, when the substrate is completely silicon substrate, the etching process will expose a portion of the silicon substrate, and the exposed area of the silicon substrate will be oxidized. In practice, even without follow-up treatment, there is still a natural oxidation, leading to an oxide layer formed on the exposed area of the silicon substrate. For example, for a silicon substrate, a silicon oxide layer is formed on the exposed area of the silicon substrate. However, in the existing process, the thickness of the oxide layer formed in this case cannot be controlled.

Based on this, the present disclosure aims to apply bias power during the flushing process, so as to remove the organic polymers, such as photoresist layers, or other carbon-based products remaining before the flushing process, and at the same time, produce an oxide layer (such as a silicon oxide layer) with a preset thickness on the exposed area of the substrate to meet the thickness requirement. In this way, the problem that the thickness of the oxide layer formed on the exposed substrate cannot be controlled in the prior art is solved, which lays a foundation for improving the yield and meeting different needs of users.

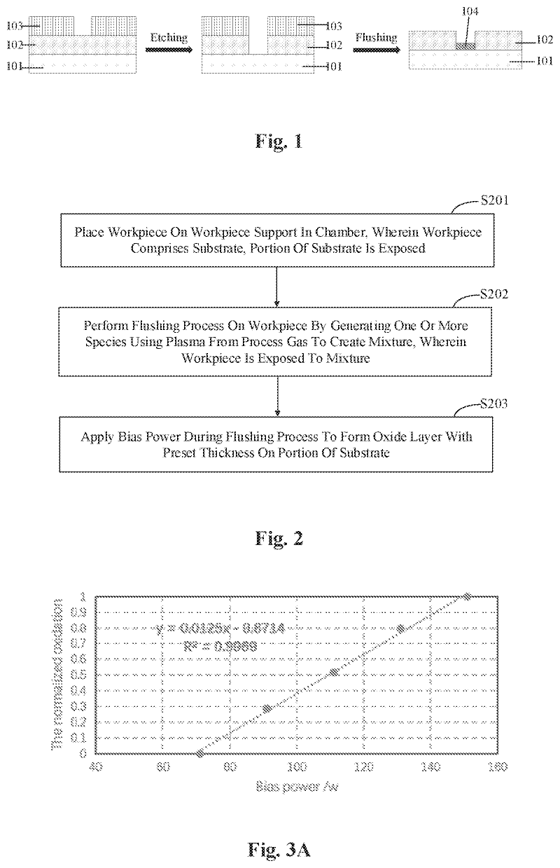

In some examples, as shown in FIG. 1, the substrate, such as silicon substrate 101, has a mask 102 formed thereon, and a photoresist layer 103 formed on the mask 102 for forming a mask pattern. The etching process etches away the non-patterned area of the mask and exposes a portion of the silicon substrate 101. Then, the flushing process is performed, and a bias power is applied during the flushing process. In this way, the residual photoresist layer 103 is removed, and at the same time, an oxide layer, such silicon oxide layer 104 with a preset thickness is formed on the exposed area of the silicon substrate 101. The thickness of the silicon oxide layer 104 meets the needs of users. In this way, the problem that the thickness of the oxide layer formed on the exposed substrate cannot be controlled in the prior art is solved, which lays a foundation for improving the yield and meeting different needs of users.

Specifically, the present disclosure provides a method for processing a workpiece, as shown in FIG. 2, the method includes:

Step S201: placing the workpiece on a workpiece support in a chamber, the workpiece includes an substrate, a portion of the substrate is exposed;

In a specific example, the workpiece includes at least a substrate and a layer structure formed on the substrate, and the layer structure includes at least an organic polymer remaining from an etching process. In addition, the etching process will expose a portion of the substrate. For example, as shown in FIG. 1, the substrate, such as silicon substrate 101, has a mask 102 formed thereon, and a photoresist layer 103 formed on the mask 102 for forming a mask pattern. The etching process etches away the non-patterned area of the mask and exposes a portion of the silicon substrate 101.

It should be noted that the layer structure shown in FIG. 1 is only an exemplary illustration. In actual applications, other layer structures may also be used, and is not restricted specifically in the present disclosure.

In a specific example, the organic polymer may specifically be photoresist remaining after the exposure and development process. Of course, in practical applications, the organic polymer may also be other substances, and is not restricted specifically in the present disclosure.

It should be noted that the chamber may be specifically a processing chamber, or a chamber functioning as a processing chamber and a plasma chamber. That is to say, in practical applications, the present disclosure is applicable to a plasma processing apparatus including separated processing chamber and plasma chamber, and in this case, the workpiece support is put in the processing chamber. Similarly, the present disclosure is applicable to a plasma processing apparatus in which the plasma chamber and the processing chamber are the same chamber. In a specific example, the plasma processing apparatus may be a plasma etching machine.

In addition, it should be noted that the workpiece described in the present disclosure may specifically be a semiconductor device or other devices. Specifically, in an example, the workpiece described in the present disclosure is a semiconductor device.

Step S202: performing a flushing process on the workpiece by generating one or more species using a plasma from a process gas to create a mixture, the workpiece is exposed to the mixture.

In practical applications, if the present disclosure is implemented on a plasma processing apparatus including separated processing chamber and plasma chamber, the step of generating plasma may be specifically performed in the plasma chamber, and then after obtaining the mixture, the mixture is introduced into the processing chamber to complete the workpiece processing flow.

In a specific example of the present disclosure, the process gas is oxygen, or a mixed gas of oxygen and nitrogen. In a specific example, when the process gas is a mixed gas of oxygen and nitrogen, the volume ratio of the two can be adjusted based on the actual situation, and is not restricted specifically in the present disclosure.

It should be noted that in practical applications, when the process gas is a mixed gas, the gases, for example, oxygen and nitrogen, can be mixed first to obtain the mixed gas, and then the mixed gas is injected into the chamber; or, the gases, for example, oxygen and nitrogen can be injected into the chamber one after the other, and the order is not restricted.

Step S203: applying a bias power during the flushing process to form an oxide layer with a preset thickness on the portion of the substrate. That is to say, after applying the bias power in the flushing process, not only the purpose of flushing, that is, the removal of residual organic polymers from the previous process, can be achieved, but also an oxide layer with a preset thickness can be formed on the exposed area of the substrate.

For example, as shown in FIG. 1, after the etching process exposes a portion of the silicon substrate 101, the flushing process is performed and a bias power is applied during the flushing process. In this way, the residual photoresist layer 103 is removed, and at the same time, an oxide layer, such silicon oxide layer 104, with a preset thickness is formed on the exposed area of the silicon substrate 101, and he thickness of the silicon oxide layer 104 meets the needs of users.

In this way, since the present disclosure can adjust the thickness of the oxide layer generated while removing the organic polymer, it solves the problem that the thickness of the oxide layer formed on the exposed substrate material cannot be controlled in the prior art, and lays a foundation for improving the yield and meeting different needs of users.

In a specific example, the mixture has a pressure and the flushing process has a time, and at least one parameter of the bias power, the pressure of the mixture, and the time of the flushing process affects a sensitivity of a thickness of the oxide layer to at least another parameter of the bias power, the pressure of the mixture, and the time of the flushing process. That is to say, after the bias power is applied in the flushing process, the bias power, the pressure of the mixture, and the time of the flushing process can all have an effect on the thickness of the oxide layer, and can also affect the sensitivity of the thickness of the oxide layer to other parameters. For example, the bias power affects the sensitivity of the thickness of the oxide layer to the pressure of the mixture; the bias power affects the sensitivity of the thickness of the oxide layer to the time of the flushing process; the pressure of the mixture affects the sensitivity of the thickness of the oxide layer to the bias power; the pressure of the mixture affects the sensitivity of the thickness of the oxide layer to the time of the flushing process, etc. therefore, based on the foregoing rules, the thickness of the oxide layer formed on the exposed area of the substrate can be adjusted to meet different needs of users.

In a specific example, the pressure of the mixture may specifically refer to the pressure in the chamber where the mixture is located. For example, when implemented on a plasma processing apparatus including separated processing chamber and plasma chamber, the pressure of the mixture may specifically be the pressure in the processing chamber, and the flushing process is implemented in the processing chamber.

In a specific example, the bias power acts on the mixture in the chamber to affect the flow of the mixture in the chamber. For example, the bias electrode is arranged under the workpiece support. Based on this, after providing a radio frequency RF power to the bias electrode, a bias power can be generated, thus affecting the flow of the mixture in the chamber.

In a specific example, the sensitivity is a slope value of the thickness of the oxide layer versus at least one parameter of the bias power, the pressure of the mixture, and the time of the flushing process. For example, the sensitivity is a slope value of the thickness of the oxide layer versus the bias power; or the sensitivity is a slope value of the thickness of the oxide layer versus the time of the flushing process; or the sensitivity is a slope value of the thickness of the oxide layer versus the pressure of the mixture. In other words, the sensitivity may specifically be the growth of the oxide layer per unit time or unit bias power.

In addition, it should be noted that those skilled in the art know that in an experiment to test the influence of one parameter on another parameter, other conditions involved in the process (that is, the values of other parameters) need to be fixed. Based on this, in a specific experimental process of the present disclosure, except for the parameters associated with sensitivity, other conditions remain unchanged. For example, if the sensitivity is a slope value of the thickness of the oxide layer versus the bias power, in the determination of the slope value, the thickness of the oxide layer and the bias power are parameters associated with the sensitivity in this experimental process, and other conditions except the thickness of the oxide layer and the bias power remain unchanged. In this way, the sensitivity of the thickness of the oxide layer to the bias power can be obtained, and lays a quantitative foundation for adjusting the thickness of the oxide layer to obtain an oxide layer with a preset thickness.

In a specific example, the pressure affects the sensitivity of the thickness of the oxide layer to the bias power. That is to say, a pressure is also applied during the flushing process, and the pressure affects the sensitivity of the thickness of the oxide layer formed on the exposed area of the substrate to the bias power. In other words, the pressure can affect the sensitivity of the thickness of the silicon oxide layer 104 shown in FIG. 1 to the bias power. Therefore, based on this feature, the time of the flushing process can be adjusted, such as reduced, and at the same time, an oxide layer with a preset thickness can be obtained, which improves the processing efficiency and meets the needs of users. Moreover, compared with the existing technology that cannot control the oxidation thickness, the present disclosure improves the controllability of the process flow to provide an flushing process that meets the requirements of different sensitivity, and further lays the foundation for providing products that meet the different needs of users and enriching the diversity of products.

In a specific example, the pressure is the pressure in the chamber where the mixture is located. For example, when implemented on a plasma processing apparatus including separated processing chamber and plasma chamber, the pressure of the mixture may specifically be the pressure in the processing chamber, and the flushing process is implemented in the processing chamber. Of course, when implemented on a plasma processing apparatus in which implemented on a plasma processing apparatus are the same chamber, the pressure is the pressure in the chamber in which the flushing process is implemented.

In a specific example, the pressure is decreased from a first pressure value to a second pressure value, to increase the sensitivity of the thickness of the oxide layer to the bias power from a first sensitivity to a second sensitivity, the first pressure value corresponds to the first sensitivity, and the second pressure value corresponds to the second sensitivity. In other words, the first sensitivity corresponding to the pressure at the first pressure value is greater than the second sensitivity corresponding to the pressure at the second pressure value. Here, the first sensitivity represents the sensitivity of the thickness of the oxide layer formed on the exposed area of the substrate to the change of the bias power when the pressure is at the first pressure value; and the second sensitivity represents the sensitivity of the thickness of the oxide layer formed on the exposed area of the substrate to the change of the bias power when the pressure is at the first pressure value, the first pressure value is any value in the first pressure range, the second pressure value is any value in the second pressure range, and the first pressure value is greater than the second pressure value. That is to say, compared with higher pressure, the thickness of the oxide layer formed on the exposed area of the substrate is more sensitive to the bias power at lower pressure.

In a specific example, the pressure of the flushing process can be reduced to increase the sensitivity of the thickness of the silicon oxide layer to the bias power in the flushing process, thereby optimizing the time of the flushing process to meet different process requirements.

In a specific example the present disclosure, the value of the pressure ranges from about 5 millitorr (mt) to about 90 millitorr (mt). For example, in some examples, the pressure is about 50 mt, or about 70 mt, or about 10 mt, or about 30 mt, or about 5 mt, or about 90 mt, etc., and the specific value is not restricted in the present disclosure.

In a specific example, the bias power affects the sensitivity of the thickness of the oxide layer to the time of the flushing process. That is to say, adjusting the bias power can adjust the sensitivity of the thickness of the oxide layer formed on the exposed area of the substrate to the time. Therefore, one can adjust the time of the flushing process and at the same time, obtain an oxide layer with a preset thickness. In this way, on the basis of improving the processing efficiency, an oxide layer that meets the thickness requirement is obtained. Compared with the existing technology that cannot control the oxide thickness, the present disclosure improves the controllability of the process flow, can provide an flushing process that meets different sensitivity requirements, and further lays a foundation for providing products that meet the different needs of users.

In a specific example, the bias power is increased from a first bias power to a second bias power, to increase the sensitivity of the thickness of the oxide layer to the time from a third sensitivity to a fourth sensitivity, the first bias power corresponds to the third sensitivity, and the second bias power corresponds to the fourth sensitivity. That is to say, the third sensitivity corresponding to the first bias power is smaller than the fourth sensitivity corresponding to the second bias power. Here, the third sensitivity represents the sensitivity of the thickness of the oxide layer formed on the exposed area of the substrate to the time under the condition of the first bias power; and the fourth sensitivity represents the sensitivity of the thickness of the oxide layer formed on the exposed area of the substrate to the time under the condition of the second bias power, the first bias power is any value in the first bias range, the second bias power is any value in the second bias range, and the first bias power is less than the second bias power. That is to say, compared with smaller bias power, the thickness of the oxide layer formed on the exposed area of the substrate is more sensitive to the bias power at larger bias power.

In a specific example of the present disclosure, the value range of the bias power is about 50 watts to about 200 watts. For example, in some examples, the bias power is about 50 watts, or about 200 watts, or about 100 watts, or about 150 watts, etc., and the specific value is not restricted in the present disclosure.

In a specific example, the bias power is proportional to the thickness of the oxide layer formed on the exposed area of the substrate. Therefore, in a certain range, for example, when the bias power is within a range, increasing the bias power can increase the thickness of the oxide layer formed on the exposed area of the substrate, such as the thickness of the silicon oxide layer 104 shown in FIG. 1; and on the other hand, reducing the bias power can reduce the oxide layer formed on the exposed area of the substrate, such as the thickness of the silicon oxide layer 104 shown in FIG. 1. In this way, during the flushing process, the control of the thickness of the oxide layer is realized, which lays a foundation for meeting the requirements of different processes.

In a specific example, the time also affects the sensitivity of the thickness of the oxide layer to the bias power. That is, adjusting the time can adjust the sensitivity of the thickness of the oxide layer formed on the exposed area of the substrate to the bias power, so as to obtain an oxide layer with a preset thickness. For example, at shorter time, the thickness of the oxide layer is highly sensitive to the bias power, while after a prolonged time, the thickness of the oxide layer is less sensitive to the bias power reduce.

In some examples, the pressure and the bias power can be applied to the chamber at the same time, and the order of application is not restricted specifically in the present disclosure. Here, for the plasma processing apparatus including separated processing chamber and plasma chamber, the pressure and the bias power described in the present disclosure are simultaneously applied to the processing chamber.

In a specific example of the present disclosure, the preset thickness is about 20 angstroms to about 50 angstroms. That is, the thickness of the oxide layer formed on the exposed area of the substrate is about 20 angstroms to about 50 angstroms. For example, in some examples, the preset thickness is about 20 angstroms, or about 50 angstroms, or about 30 angstroms, or about 35 angstroms, or about 40 angstroms, etc., and the specific value is not restricted in the present disclosure. In this way, it has laid the foundation for providing products that meet the different needs of users.

In a specific example, the processing parameters of the chamber further include one or more of:

Source power: about 500 watts to about 1000 watts; for example, in some examples, the source power is about 1000 watts; or about 500 watts, or about 800 watts, or about 700 watts, or about 950 watts, and is not restricted specifically in the present disclosure and can be modulated based on actual needs.

O₂: about 100 standard cubic centimeters per minute to about 500 standard cubic centimeters per minute; for example, in some examples, O₂ is provided at about 100 standard cubic centimeters per minute; or about 500 standard cubic centimeters per minute, or about 200 standard cubic centimeters per minute, or about 300 standard cubic centimeters per minute, or about 450 standard cubic centimeters per minute, and is not restricted specifically in the present disclosure and can be modulated based on actual needs.

N₂: about 100 standard cubic centimeters per minute to about 300 standard cubic centimeters per minute; for example, in some examples, N₂ is provided at about 100 standard cubic centimeters per minute; or about 300 standard cubic centimeters per minute, or about 200 standard cubic centimeters per minute, or about 150 standard cubic centimeters per minute, or about 250 standard cubic centimeters per minute, and is not restricted specifically in the present disclosure and can be modulated based on actual needs.

Temperature: about 20° C. to about 50° C.; for example, in some examples, the temperature is about 20° C.; or about 50° C.; or about 30° C.; or about 45° C., and is not restricted specifically in the present disclosure and can be modulated based on actual needs.

It should be noted that in the present disclosure, the use of the term “about” in combination with a numerical value is intended to be within ten percent (10%) of the indicated value.

In this way, the present disclosure can obtain an oxide layer with a preset thickness while removing the organic polymer, solve the problem in the prior art that the thickness of the oxide layer generated on the exposed substrate material cannot be adjusted, laid the foundation for improving the yield and meeting the different needs of users.

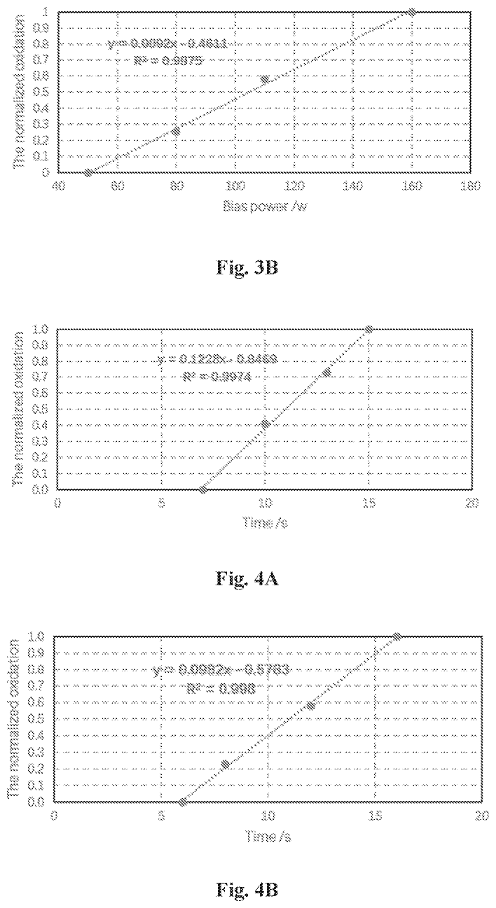

For example, in a specific example, based on the mattson paradigm XP2 platform, an inductively coupled plasma chamber equipped with a Faraday shield (that is, the chamber described above) is used to complete the etching process and the flushing process. Specifically, a flushing process is performed on the workpiece using a plasma obtained by using oxygen or a mixed gas of oxygen and nitrogen as the process gas to remove the residual organic polymer, and after the flushing process, a silicon oxide layer is formed on the exposed area of the silicon substrate. Furthermore, the thickness of the silicon oxide layer can be obtained by measuring the silicon oxide layer formed by a film thickness measuring machine. Based on the different flushing process conditions and the measured thickness of the silicon oxide layer, the schematic diagrams shown in FIGS. 3 to 5 can be obtained; among them, as shown in FIG. 3A, the ordinate corresponds to the thickness (mathematic ally processed thickness), the abscissa represents the bias power, and R² represents the fitting coefficient in the data processing process. In this case, at fixed pressure, such as lower pressure (such as 5 mt-20 mt), the schematic diagrams shown FIG. 3A can be obtain. As can be seen from FIG. 3A, the sensitivity of the thickness of the silicon oxide layer to the bias power in the flushing process is 0.0125 at the lower pressure. As shown in FIG. 3(B), the ordinate corresponds to the thickness, the abscissa represents the bias power, and R² represents the fitting coefficient during data processing. In this case, at fixed pressure, such as higher pressure (such as 21 mt-70 mt), the schematic diagrams shown FIG. 3B can be obtain. As can be seen from FIG. 3B, the sensitivity of the thickness of the silicon oxide layer to the bias power in the flushing process is 0.0092 at the higher pressure. Compared with lower pressure, as shown in FIG. 3A, the sensitivity at higher pressure is relatively lower.

Similarly, as shown in FIG. 4A, the ordinate corresponds to the thickness, the abscissa represents the time, and R² represents the fitting coefficient in the data processing process. In this case, at fixed bias power, such as higher bias power (e.g., 101 w-200 w), the schematic diagrams shown FIG. 4A can be obtain. As can be seen from FIG. 4A, the sensitivity of the thickness of the silicon oxide layer to the time in the flushing process is 0.1228 at the higher bias power. As shown in FIG. 4B, the ordinate corresponds to the thickness, the abscissa represents the time, and R² represents the fitting coefficient in the data processing process. In this case, at fixed bias power, such as lower bias power (e.g., 50 w-100 w), the schematic diagrams shown FIG. 4B can be obtain. As can be seen from FIG. 4B, the sensitivity of the thickness of the silicon oxide layer to the time in the flushing process is 0.0982 at the lower bias power. Compared with higher bias power, as shown in FIG. 4A, the sensitivity at lower bias power is relatively lower.

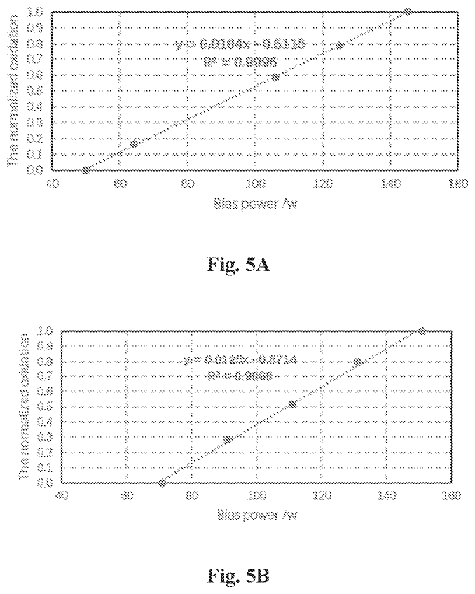

Similarly, as shown in FIG. 5A, the ordinate corresponds to the thickness, the abscissa represents the bias power, and R² represents the fitting coefficient in the data processing process. In this case, at fixed time, such as longer time, the schematic diagrams shown FIG. 5A can be obtain. As can be seen from FIG. 5A, the sensitivity of the thickness of the silicon oxide layer to the bias power is 0.0104 at the longer time. As shown in FIG. 5B, the ordinate corresponds to the thickness, the abscissa represents the bias power, and R² represents the fitting coefficient in the data processing process. In this case, at fixed time, such as shorter time, the schematic diagrams shown FIG. 5B can be obtain. As can be seen from FIG. 5B, the sensitivity of the thickness of the silicon oxide layer to the bias power is 0.0125 at the shorter time. Compared with longer time, as shown in FIG. 5A, the sensitivity at shorter time is relatively higher.

In this way, the present disclosure can adjust thickness of an oxide layer while removing the organic polymer, solve the problem in the prior art that the thickness of the oxide layer generated on the exposed substrate material cannot be adjusted, laid the foundation for improving the yield and meeting the different needs of users.

The present disclosure also provides a plasma processing apparatus. The plasma processing includes a plasma chamber operable to receive a process gas. The plasma processing includes a processing chamber having a workpiece support operable to support a workpiece and a bias electrode for generating a bias power. The workpiece includes a substrate, a portion of the substrate is exposed, and the bias electrode is arranged under the workpiece support. The plasma processing includes an inductive element operable to induce a plasma from the process gas. The plasma processing includes a bias source configured to provide a radio frequency (RF) power to the inductive element and the bias electrode. The plasma processing includes a controller configured to control the inductive element, the bias electrode and the bias source to implement a flushing process. The flushing process include operations. The operations include providing a first RF power to the inductive element to generate the plasma from the process gas to generate a mixture, the mixture including one or more species. The workpiece in the processing chamber is exposed to the mixture for a flushing process. The operations further include providing a second RF power to the bias electrode to apply a bias power during the flushing process, so that an oxide layer with a preset thickness is formed on the portion of the substrate.

It should be noted that the present disclosure can use any plasma source, for example, an inductively coupled plasma source, a capacitively coupled plasma source, etc., which is not restricted specifically.

In a specific example of the present disclosure, the processing chamber and the plasma chamber are the same chamber.

In a specific example of the present disclosure, the mixture has a pressure and the flushing process has a time, at least one parameter of the bias power, the pressure of the mixture, and the time of the flushing process affects a sensitivity of a thickness of the oxide layer to at least another parameter of the bias power, the pressure of the mixture, and the time of the flushing process.

In a specific example of the present disclosure, the sensitivity is a slope value of the thickness of the oxide layer versus at least one parameter of the bias power, the pressure of the mixture, and the time of the flushing process.

In a specific example of the present disclosure, the pressure affects the sensitivity of the thickness of the oxide layer to the bias power.

In a specific example of the present disclosure, the pressure is the pressure in the processing chamber where the mixture is located.

In a specific example of the present disclosure, the pressure is in a range of about 5 mt to about 90 mt.

In a specific example of the present disclosure, the controller is further configured to decrease the pressure from a first pressure value to a second pressure value, to increase the sensitivity of the thickness of the oxide layer to the bias power from a first sensitivity to a second sensitivity. The first pressure value corresponds to the first sensitivity, and the second pressure value corresponds to the second sensitivity.

In a specific example of the present disclosure, the bias power affects the sensitivity of the thickness of the oxide layer to the time of the flushing process.

In a specific example of the present disclosure, the controller is further configured to increase the bias power from a first bias power to a second bias power, to increase the sensitivity of the thickness of the oxide layer to the time from a third sensitivity to a fourth sensitivity. The first bias power corresponds to the third sensitivity, and the second bias power corresponds to the fourth sensitivity.

In a specific example of the present disclosure, the bias power is in a range of about 50 watts to about 200 watts.

In a specific example of the present disclosure, the bias power is proportional to the preset thickness.

In a specific example of the present disclosure, the preset thickness is in a range of about 20 angstroms to about 50 angstroms.

Some embodiments of the present disclosure correspond to those of the above methods, and will not be repeated here.

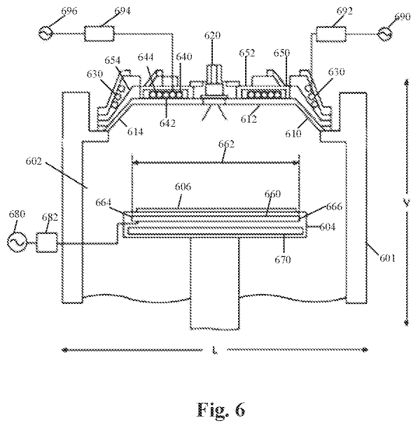

In a specific example, the plasma processing apparatus may specifically be a plasma etching machine, as shown in FIG. 6, which may include a processing chamber 601 defining a vertical direction V and a lateral direction L.

The plasma etching machine may include a pedestal (that is, a workpiece support) 604 provided in the internal space 602 of the processing chamber 601. The pedestal 604 may be configured to, in the internal space 602, support the substrate or the workpiece 606 to be etched. A dielectric window 610 is located above the pedestal 604 and serves as the top plate of the internal space 602. The dielectric window 610 includes a central portion 612 and an angled peripheral portion 614. The dielectric window 610 includes a space for the shower head 620 in the central portion 612 to inject a processing gas, such as an etching gas, into the inner space 602.

In some embodiments, the plasma processing apparatus may include a plurality of inductive elements, such as a primary inductive element 630 and a secondary inductive element 640, for generating induced plasma in the internal space 602. The primary inductive element 630 and the secondary inductive element 640 may each include a coil or an antenna element, and when supplied with RF power, may induce plasma in the processing gas in the internal space 602 of the processing chamber 601. For example, a first RF generator 690 may be configured to provide electromagnetic energy to the primary inductive element 630 through a matching network 692. A second RF generator 696 may be configured to provide electromagnetic energy to the secondary inductive element 640 through a matching network 694.

Although terms such as primary inductive element and secondary inductive element are used in the present disclosure, it should be noted that the terms primary and secondary are used for convenience only and are not used to limit the present disclosure. Moreover, in practical applications, the secondary coil can be operated independently of the primary coil, and the primary coil can be operated independently of the secondary coil. In addition, in some embodiments, the plasma processing apparatus may only have a single inductive coupling element.

In some embodiments, the plasma processing apparatus may include a metal shield 652 disposed around the secondary inductive element 640. In this way, the metal shield 652 separates the primary inductive element 630 and the secondary inductive element 640 to reduce the crosstalk between the primary inductive element 630 and the secondary inductive element 640.

In some embodiments, the plasma processing apparatus may include a first Faraday shield 654 disposed between the primary inductive element 630 and the dielectric window 610. The first Faraday shield 654 may be a slotted metal shield that reduces the capacitive coupling between the primary inductive element 630 and the processing chamber 601. As shown in FIG. 6, the first Faraday shield 654 may be fitted over the angled portion of the dielectric window 610.

In some embodiments, the metal shield 652 and the first Faraday shield 654 may form a single body 650 for ease of manufacturing or other purposes. The multiple turns of coils of the primary inductive element 630 may be located adjacent to the first Faraday shield 654 of the single body 650. The secondary inductive element 640 may be located close to the metal shield 652 of the single body 650, for example, between the metal shield 652 and the dielectric window 610.

The arrangement of the primary inductive element 630 and the secondary inductive element 640 on opposite sides of the metal shield 652 allows the primary inductive element 630 and the secondary inductive element 640 to have different structural configurations and perform different functions. For example, the primary inductive element 630 may include multiple turns of coils located near the peripheral portion of the processing chamber 601. The primary induction element 630 can be used for basic plasma generation and reliable priming during the inherent transient ignition phase. The primary inductive element 630 may be coupled to a powerful RF generator and an expensive auto-tuning matching network, and may be operated at an increased RF frequency (e.g., about 13.56 MHz).

In some embodiments, the secondary inductive element 640 may be used for correction and auxiliary functions as well as for improving the stability of the plasma during steady-state operation. In addition, since the secondary inductive element 640 may be mainly used for correction and auxiliary functions and to improve plasma stability during steady-state operation, the secondary inductive element 640 does not have to be coupled to a powerful RF generator like the primary inductive element 630. Therefore, different and cost-effective designs can be made to overcome the difficulties associated with previous designs. As discussed in detail below, the secondary inductive element 640 can also be operated at a lower frequency (for example, about 2 MHz), enabling the secondary inductive element 640 to be very compact and can fit in the restricted space on top of the dielectric window.

In some embodiments, the primary inductive element 630 and the secondary inductive element 640 may be operated at different frequencies. The frequencies may be sufficiently different to reduce plasma crosstalk between the primary inductive element 630 and the secondary inductive element 640. For example, the frequency applied to the primary inductive element 630 may be at least about 1.5 times the frequency applied to the secondary inductive element 640. In some embodiments, the frequency applied to the primary inductive element 630 may be about 13.56 MHz, and the frequency applied to the secondary inductive element 640 may be in the range of about 1.75 MHz to about 2.15 MHz. Other suitable frequencies can also be used, such as about 400 kHz, about 4 MHz, and about 27 MHz. Although the present disclosure is discussed with reference to the primary inductive element 630 operating at a higher frequency relative to the secondary inductive element 640, according to the disclosure provided herein, those skilled in the art should understand that the secondary inductive element 640 can be operated at a higher frequency, without departing from the scope of the present disclosure.

In some embodiments, the secondary inductive element 640 may include a planar coil 642 and a magnetic flux concentrator 644. The magnetic flux concentrator 644 may be made of ferrite material. Using a magnetic flux concentrator with an appropriate coil can enable the secondary inductive element 640 to have higher plasma coupling and good energy transmission efficiency, and can significantly reduce its coupling with the metal shield 652. Using a lower frequency (for example, about 2 MHz) on the secondary induction element 640 can increase the skin layer, which also improves the plasma heating efficiency.

In some embodiments, the primary inductive element 630 and the secondary inductive element 640 may have different functions. For example, the primary inductive element 630 may be used to perform the basic function of plasma generation during ignition and provide sufficient priming for the secondary inductive element 640. The primary inductive element 630 may have couplings to both the plasma and the ground shield to stabilize the plasma potential. The first Faraday shield 654 associated with the primary inductive element 630 avoids window sputtering and may be used to provide coupling to the ground shield.

An additional coil may be operated in the presence of a good plasma priming provided by the primary induction element 630, and therefore, the additional coil preferably has good plasma coupling to the plasma and good energy transfer efficiency. The secondary inductive element 640 including the magnetic flux concentrator 644 not only provides good magnetic flux transfer to the plasma volume, but also provides good decoupling between the secondary inductive element 640 and a surrounding metal shield 652. The symmetrical driving of the magnetic flux concentrator 644 and the secondary inductive element 640 further reduces the voltage amplitude between the coil end and the surrounding ground element. This can reduce the sputtering of the dome, but at the same time it will bring some small capacitive coupling to the plasma, which can be used to aid ignition. In some embodiments, a second Faraday shield can be used in combination with the secondary inductive element 640 to reduce the capacitive coupling of the secondary inductive element 640.

In some embodiments, the plasma processing apparatus may include a radio frequency (RF) bias electrode 660 disposed in the processing chamber 601. The plasma processing apparatus may further include a ground plane 670 disposed in the processing chamber 601 such that the ground plane 670 is spaced apart from the RF bias electrode 660 along the vertical direction V. As shown in FIG. 6, in some embodiments, the RF bias electrode 660 and the ground plane 670 may be disposed in the pedestal 604.

In some embodiments, the RF bias electrode 660 may be coupled to the RF power generator 680 via a suitable matching network 682. When the RF power generator 680 provides RF energy to the RF bias electrode 660, plasma may be generated from the mixture in the processing chamber 601 to be directly exposed to the substrate 606. In some embodiments, the RF bias electrode 660 may define an RF region 662 extending along the lateral direction L between the first end 664 of the RF bias electrode 660 and the second end 666 of the RF bias electrode 660. For example, in some embodiments, the RF region 662 may span from the first end 664 of the RF bias electrode 660 to the second end 666 of the RF bias electrode 660 along the lateral direction L. The RF region 662 may further extend along the vertical direction V between the RF bias electrode 660 and the dielectric window 610.

It should be understood that the length of the ground plane 670 along the lateral direction L is greater than the length of the RF bias electrode 660 along the lateral direction L. In this way, the ground plane 670 can direct the RF energy emitted by the RF bias electrode 660 to the substrate 606.

It should be noted that in the present disclosure, the use of the term “about” in combination with a numerical value is intended to be within ten percent (10%) of the indicated value.

Here, the structure shown in FIG. 6 is only exemplary. In practical applications, the plasma processing apparatus may also include other functional components based on actual requirements, and is not restricted specifically in the present disclosure.

The present disclosure also provides a semiconductor device including a workpiece processed by a method as described above, the workpiece includes a substrate, and an oxide layer formed on the exposed area of the substrate has a thickness of about 20 angstroms to about 50 angstroms. For example, in some examples, the thickness of the oxide layer is about 20 angstroms, or about 50 angstroms, or about 30 angstroms, or about 35 angstroms, or about 40 angstroms, etc., and it is not restricted specifically in the present disclosure. In this way, it has laid the foundation for providing products that meet the different needs of users.

In an example, the semiconductor device may specifically be a logic processor, a memory, and/or the like.

It should be understood that various forms of the processes shown above can be used, including reordering, adding or deleting step(s). For example, the steps described in the present disclosure can be executed in parallel, sequentially, or in a different order, as long as a desired result of the technical solution disclosed in the present disclosure can be achieved, and they are not restricted in the present disclosure.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged in whole or in part. Furthermore, those of ordinary skill in the art will appreciate that the foregoing description is by way of example only and is not intended to limit the invention so further described in such appended claims.

What is claimed is:

1. A method for processing a workpiece, comprising:
placing the workpiece on a workpiece support in a chamber, wherein the workpiece comprises a substrate, a portion of the substrate is exposed;
performing a flushing process on the workpiece by generating one or more species using a plasma from a process gas to create a mixture, wherein the workpiece is exposed to the mixture; and
applying a bias power during the flushing process to form an oxide layer with a preset thickness on the portion of the substrate.

2. The method of claim 1, wherein the mixture has a pressure and the flushing process has a time, wherein at least one parameter of the bias power, the pressure of the mixture, and the time of the flushing process affects a sensitivity of a thickness of the oxide layer to at least another parameter of the bias power, the pressure of the mixture, and the time of the flushing process.

3. The method of claim 1, wherein the bias power acts on the mixture in the chamber to affect a flow of the mixture in the chamber.

4. The method of claim 2, wherein the sensitivity is a slope value of the thickness of the oxide layer versus at least one parameter of the bias power, the pressure of the mixture, and the time of the flushing process.

5. The method of claim 2, wherein the pressure affects the sensitivity of the thickness of the oxide layer to the bias power.

6. The method of claim 2, wherein the pressure is the pressure in the chamber where the mixture is located.

7. The method of claim 6, wherein the pressure is in a range of about 5 mTorr (mt) to about 90 mt.

8. The method of claim 5, further comprising:
decreasing the pressure from a first pressure value to a second pressure value, to increase the sensitivity of the thickness of the oxide layer to the bias power from a first sensitivity to a second sensitivity;
wherein the first pressure value corresponds to the first sensitivity, and the second pressure value corresponds to the second sensitivity.

9. The method of claim 1, wherein the bias power affects the sensitivity of the thickness of the oxide layer to the time of the flushing process.

10. The method of claim 9, further comprising:
increasing the bias power from a first bias power to a second bias power, to increase the sensitivity of the thickness of the oxide layer to the time from a third sensitivity to a fourth sensitivity;
wherein the first bias power corresponds to the third sensitivity, and the second bias power corresponds to the fourth sensitivity.

11. The method according to claim 1, wherein the bias power is in a range of about 50 watts to about 200 watts.

12. The method of claim 11, wherein the bias power is proportional to the preset thickness.

13. The method according to claim 1, wherein the preset thickness is in a range of about 20 angstroms to about 50 angstroms.

14. A plasma processing apparatus, comprising:
a plasma chamber operable to receive a process gas;
a processing chamber having a workpiece support operable to support a workpiece and a bias electrode for generating a bias power; wherein the workpiece comprises an substrate, a portion of the substrate is exposed, and the bias electrode is arranged under the workpiece support;
an inductive element operable to induce a plasma from the process gas;
a bias source configured to provide a radio frequency (RF) power to the inductive element and the bias electrode;
a controller configured to control the inductive element, the bias electrode and the bias source to implement a flushing process, the flushing process comprising operations, the operations comprising:
providing a first RF power to the inductive element to generate the plasma from the process gas to generate a mixture, the mixture comprising one or more species, wherein the workpiece in the processing chamber is exposed to the mixture for a flushing process; and
providing a second RF power to the bias electrode to apply the bias power during the flushing process, so that an oxide layer with a preset thickness is formed on the portion of the substrate.

15. The plasma processing apparatus of claim 14, wherein the processing chamber and the plasma chamber are the same chamber.

16. The plasma processing apparatus of claim 14, wherein the mixture has a pressure and the flushing process has a time, wherein at least one parameter of the bias power, the pressure of the mixture, and the time of the flushing process affects a sensitivity of a thickness of the oxide layer to at least another parameter of the bias power, the pressure of the mixture, and the time of the flushing process.

17. The plasma processing apparatus of claim 16, wherein the sensitivity is a slope value of the thickness of the oxide layer versus at least one parameter of the bias power, the pressure of the mixture, and the time of the flushing process.

18. The plasma processing apparatus of claim 16, wherein the pressure affects the sensitivity of the thickness of the oxide layer to the bias power.

19. The plasma processing apparatus of claim 16, wherein the pressure is the pressure in the processing chamber where the mixture is located.

20.-26. (canceled)

27. A semiconductor device comprising a workpiece processed by a method, the method comprising:
placing the workpiece on a workpiece support in a chamber, wherein the workpiece comprises a substrate, a portion of the substrate is exposed;
performing a flushing process on the workpiece by generating one or more species using a plasma from a process gas to create a mixture, wherein the workpiece is exposed to the mixture; and
applying a bias power during the flushing process to form an oxide layer with a preset thickness on the portion of the substrate;
wherein the thickness of the oxide layer formed on the portion of the substrate is in a range of about 20 angstroms to about 50 angstroms.
